(19) United States
(12) Patent Application Publication
(10) Pub. No.: US 2013/0142361 A1
(43) Pub. Date: Jun. 6, 2013

(54) METHOD FOR CONTROLLING ALTITUDE INFORMATION-BASED USER FUNCTIONS AND MOBILE DEVICE ADAPTED THERETO

(71) Applicant: SAMSUNG ELECTRONICS CO. LTD., Suwon-si (KR)

(72) Inventor: Hoyeong LIM, Seongnam-si (KR)

(73) Assignee: SAMSUNG ELECTRONICS CO. LTD., Suwon-si (KR)

(21) Appl. No.: 13/680,592

(22) Filed: Nov. 19, 2012

(30) Foreign Application Priority Data
Dec. 2, 2011 (KR) 10-2011-0128262

(51) Int. Cl. H03G 3/20

(52) U.S. Cl. CPC H03G 3/20
USPC 381/107

(57) ABSTRACT

A method for controlling altitude information-based user functions and a mobile device adapted thereto are provided. The mobile device includes a storage unit for storing audio data that will be output according to the activation of a user function, and auxiliary data that will be applied to the audio data if an audio data altering function is set when the user function is activated, a sensing unit for collecting altitude information to set auxiliary data that will be applied to the audio data according to the activation of the user function, a controller for creating altered audio data by applying predefined auxiliary data to audio data that will be output when the user function is executed, according to the altitude information, and an audio processing unit for outputting the altered audio data.

### PRIORITY

This application claims the benefit under 35 U.S.C. §119(a) of a Korean patent application filed on Dec. 2, 2011 in the Korean Intellectual Property Office and assigned Serial No. 10-2011-0128262, the entire disclosure of which is hereby incorporated by reference.

### BACKGROUND OF THE INVENTION

1. Field of the Invention

This invention relates to an apparatus and method for controlling functions of a mobile device. More particularly, this invention relates to an apparatus and method for controlling user functions in a mobile device based on altitude information regarding a location of the mobile device and for outputting data according to the conditions.

2. Description of the Related Art

Mobile devices are widely used because they provide a variety of user functions and are relatively small so that they are easily carried. Mobile devices also alter user functions according to the settings and the state information in order to provide greater convenience. For example, mobile devices allow the users to execute an audio data output function and set the audio data output modes to hear desired audio sounds. However, the conventional audio data output function only serves to output audio data according to the mobile device user's settings without any additional services.

Mobile devices of the related art operate in a variety of environments, e.g., homes, offices, places where noise exists, where weather conditions or atmospheric pressure substantially vary, etc. Although mobile devices must operate in such a variety of environments, they output audio data only in fixed modes. That is, conventional mobile devices cannot be adaptively controlled to output audio data to satisfy the users' preferences.

Therefore, a need exists for an apparatus and method for adaptively controlling user functions in a mobile device based on altitude information regarding a location of the mobile device.

### SUMMARY OF THE INVENTION

Aspects of the present invention are to address at least the above-mentioned problems and/or disadvantages and to provide at least the advantages described below. Accordingly, an aspect of the present invention is to provide a method that adaptively controls user functions in a mobile device based on altitude information regarding a location of the mobile device.

Another aspect of the present invention is to provide a mobile device adapted to the method.

In accordance with an aspect of the present invention, a method for controlling altitude information-based user functions is provided. The method includes receiving a request for the activation of a user function, activating a sensing unit according to the activated user function, collecting, by the sensing unit, altitude information, creating altered audio data by applying predefined auxiliary data to audio data that will be output when the user function is executed, according to the altitude information, and outputting the altered audio data.

In accordance with another aspect of the present invention, a mobile device that supports altitude information-based user functions is provided. The mobile device includes a storage unit for storing audio data that will be output according to the activation of a user function, and auxiliary data that will be applied to the audio data if an audio data altering function is set when the user function is activated, a sensing unit for collecting altitude information to set auxiliary data that will be applied to the audio data according to the activation of the user function, a controller for creating altered audio data by applying predefined auxiliary data to audio data that will be output when the user function is executed, according to the altitude information, and an audio processing unit for outputting the altered audio data.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a schematic block diagram of a mobile device according to an exemplary embodiment of the present invention;

FIG. 2 illustrates a controller according to an exemplary embodiment of the present invention;

FIG. 3 illustrates screens to describe a method for controlling altitude information-based user functions in a mobile device according to a first exemplary embodiment of the present invention;

FIG. 4 illustrates a screen to describe a method for controlling altitude information-based user functions in a mobile device according to a second exemplary embodiment of the present invention; and

FIG. 5 illustrates a flowchart that describes a method for controlling altitude information-based user functions in a mobile device according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

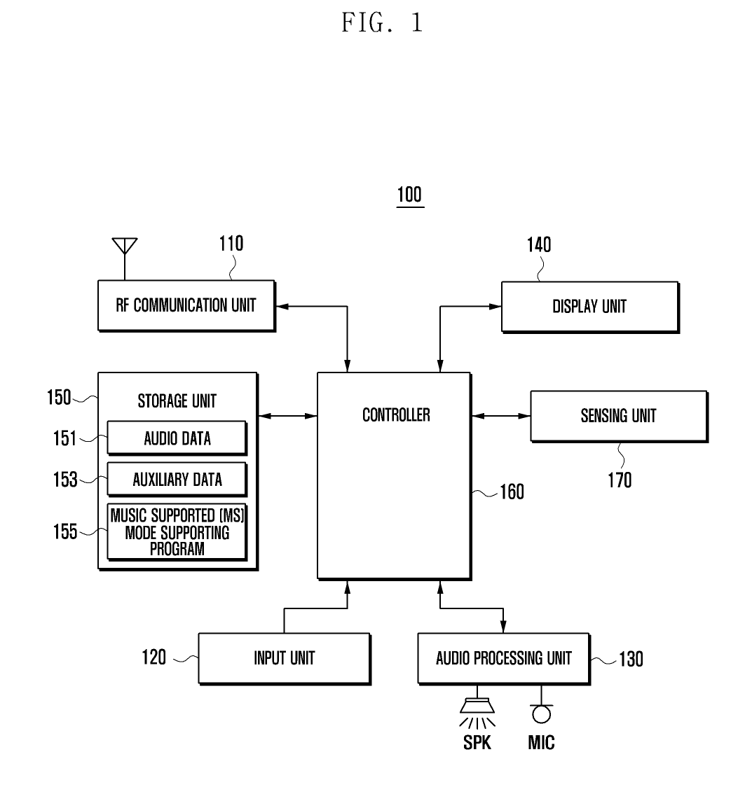

FIG. 1 illustrates a schematic block diagram of a mobile device according to an exemplary embodiment of the present invention.

Referring to FIG. 1, a mobile device 100 includes an RF communication unit 110, an input unit 120, an audio processing unit 130, a display unit 140, a storage unit 150, a sensing unit 170, and a controller 160.

The mobile device 100 supports a change in data of a user function based on altitude information regarding a location of the mobile device 100 collected by the sensing unit 170. The mobile device 100 may process data, in different modes, with respect to the same user function, according to the environment information, e.g., altitude information. That is, the mobile device 100 can provide a variety of user functions adapting to altitude information.

The RF communication unit 110 may be installed in the mobile device 100 if the mobile device 100 is designed to provide a communication function. If the mobile device 100 does not support a communication, it may not include the RF communication unit 110. The RF communication unit 110 may be implemented with a mobile communication module for supporting a communication function, or a mobile communication function, in the mobile device 100. The RF communication unit 110 establishes a communication channel with a mobile communication system and transmits signals between the mobile device 100 and the system via the communication channel. Examples of the communication channel are a voice service channel, a video service channel, a data service channel, etc.

The RF communication unit 110 transmits data related to the operation of the sensing unit 170. For example, if the altitude information collected by the sensing unit 170 has a preset level, the RF communication unit 110 may transmit auxiliary data, previously defined, when transmitting audio data corresponding to a voice signal, or audio data synthesized with auxiliary data. Alternatively, the RF communication unit 110 may output audio data that is modulated based on auxiliary data. The function of outputting altered audio data from the RF communication unit 110 may be released according to a user's settings. The function of transmitting altered audio data from the RF communication unit 110 may be set according to the change in the altitude information collected by the sensing unit 170. That is, the auxiliary data may be varied according to the change in the altitude information.

Auxiliary data refers to values for altering audio data, e.g., melodies, chords, etc. Auxiliary data also serves to control functions related to sound effects, e.g., a turn-table function, a jukebox function, a scratching function, a howling function, etc. Auxiliary data may be data to alter audio sounds output when a specific user function is activated.

The input unit 120 creates signals to operate the mobile device 100. The input unit 120 may be implemented with a keyboard, a keypad, key buttons, etc., according to types of mobile devices. If the display unit 140 is implemented with a touch screen, the input unit 120 may be a touch map. The input unit 120 creates signals for setting user functions to alter according to altitude information. That is, if the altitude information is altered, the input unit 120 creates signals, according to a user's request, for determining whether to alter the operation setting of a specific user function. The input unit 120 may also create signals for matching auxiliary data with altitude information and for selecting particular data from the auxiliary data in a particular altitude state, according to a user's request. The signals created in the input unit 120 are transferred to the controller 160 and serve as commands for supporting corresponding functions.

The audio processing unit 130 outputs audio data set during the operation of the mobile device 100, audio data created when audio files stored in the storage unit 150 are played back, audio data received from the outside of the mobile device 100, etc. The audio processing unit 130 supports a function for collecting audio data. To this end, the audio processing unit 130 includes a speaker (SPK) and a microphone (MIC). In an exemplary embodiment of the invention, the audio processing unit 130 outputs audio data to which auxiliary data is applied.

The display unit 140 provides a variety of screen interfaces for controlling the mobile device 100. For example, the display unit 140 displays an idle screen, a menu screen, etc. The display unit 140 may also display a screen when a user function is executed, and a screen to determine whether to set a Music Supported (MS) mode where, if a user function is the output of audio data, the audio data is altered based on altitude information. When the MS mode is activated, the display unit 140 displays a screen for selecting data, corresponding to specific altitude information, from auxiliary data. A more detailed description of the screens provided by the display unit 140 will be explained later referring to the accompanying drawings.

The display unit 140 may be implemented with a touch screen including a display panel and a touch panel. The display panel displays the screens described above, including images, text, etc. The touch panel includes a touch effective area and a touch ineffective area, cooperating with the display panel. The touch panel creates signals corresponding to touch events that occurred on the touch effective area and transfers them to the controller 160.

The storage unit 150 stores an operating system for controlling the mobile device 100, application programs related to the invention, etc. The storage unit 150 stores a program 155 for supporting the MS mode. The storage unit 150 also stores auxiliary data 153 and audio data 151 for operating the MS mode supporting program 155.

The MS mode supporting program 155 includes sub-routines for supporting audio data altering functions. The MS mode supporting program 155 is loaded on the controller 160 in a specific state and supports an audio data altering function. For example, the MS mode supporting program 155 can be called and controlled by the controller 160 in order to execute a specific user function with an audio data output function. The MS mode supporting program 155 includes a sub-routine for detecting whether a user function with an audio data output function is activated, a sub-routine for determining whether an MS mode is set in order to execute a corresponding user function, a sub-routine for activating the sensing unit 170 when an MS mode is set, etc. The MS mode supporting program 155 may also include a sub-routine for identifying altitude information collected by the sensing unit 170, a sub-routine for selecting auxiliary data 153 corresponding to specific altitude information, a sub-routine for applying the selected auxiliary data 153 to audio data 151 and creating the altered audio data, a sub-routine for outputting the altered audio data, etc. More particularly, the sub-routine for creating the altered audio data may include sub-routines for synthesizing audio data 151 with auxiliary data 153, for modulating audio data 151 based on auxiliary data 153, and for selecting auxiliary data 153 that is output, independent of audio data 151. The MS mode supporting program 155 also includes a sub-routine for outputting, if altitude information is previously set, a data list included in auxiliary data 153, and a sub-routine for applying data selected from the data list to audio data 151 to be output and outputting it.

The audio data 151 includes data that is output via the audio processing unit 130 according to the operation of a specific user function. The auxiliary data 153 refers to data that is used to alter the output property of audio data 151, e.g., melodies to be synthesized with audio data 151, functions for modulating the audio data 151, or a melody or a tune that is output, independent of audio data 151.

The sensing unit 170 includes at least one sensor for collecting altitude information regarding a current location of the mobile device 100. The sensing unit 170 may be implemented with a pressure sensor, or an altitude sensor, for determining the altitude. The accuracy of the sensing unit 170 may be dependent on the manufactured design. For example, the sensing unit 170 may determine the barometric pressure as the mobile device 100 varies its altitude per 25 cm above sea level. If the sensing unit 170 is more accurate, it may have a fine resolution for determining a minute change in altitude when the mobile device 100 is moved. On the contrary, the sensing unit 170 may have a less accurate resolution for determining the change in altitude than the resolution described above, according to the manufacturers' designs. The sensing unit 170 transfers the measured altitude information to the controller 160.

The controller 160 controls signals flowing among the components in the mobile device 100, and the collecting of information and outputting of corresponding information, in order to support an audio data altering function. To this end, the controller 160 also collects audio data 151 related to a currently activated user function, controls the sensing unit 170, and alters the format of audio data 151 based on specific auxiliary data 153 and altitude information collected by the sensing unit 170.

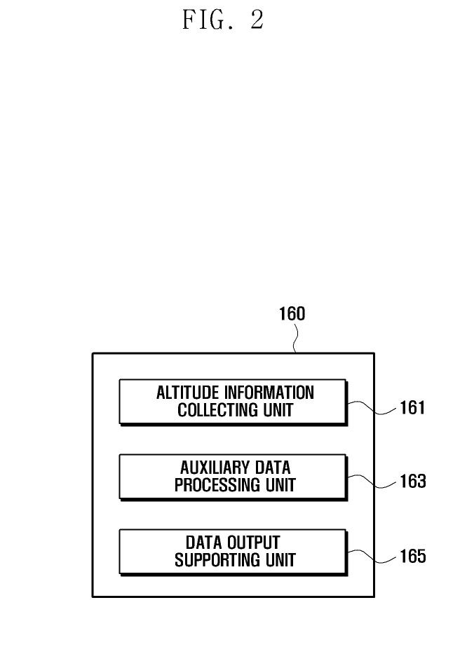

FIG. 2 illustrates a controller according to an exemplary embodiment of the present invention.

Referring to FIG. 2, a controller 160 includes an altitude information collecting unit 161, an auxiliary data processing unit 163, and a data output supporting unit 165.

The altitude information collecting unit 161 collects altitude information regarding a location of the mobile device 100. When a specific user function is executed in the mobile device 100, the altitude information collecting unit 161 determines whether an MS mode for the function is set. If the user function is executed in the MS mode, the altitude information collecting unit 161 controls the sensing unit 170 to collect altitude information. That is, the altitude information collecting unit 161 supplies electric power to the sensing unit 170 and initializes the sensing unit 170 to collect altitude information. After completing the initialization, the sensing unit 170 collects altitude information regarding a location of the mobile device 100 and transfers the information to the altitude information collecting unit 161. The altitude information collecting unit 161 transfers the collected altitude information to the auxiliary data processing unit 163. The altitude information collecting unit 161 identifies the set levels corresponding to the collected altitude information and transfers the level information to the auxiliary data processing unit 163. When the user function is not enabled, the altitude information collecting unit 161 does not supply electric power to the sensing unit 170, thereby preventing the consumption of electric power.

The auxiliary data processing unit 163 applies specific auxiliary data 153 to audio data 151 according to a specific set level or altitude information from the altitude information collecting unit 161. To this end, the auxiliary data processing unit 163 identifies auxiliary data 153 matching the current altitude information and the currently activated user function, and collects corresponding auxiliary data 153. The auxiliary data processing unit 163 applies the collected auxiliary data 153 to audio data 151, thereby creating altered audio data. The altered audio data is transferred to the data output supporting unit 165. For example, if altitude information is a first set level, the auxiliary data processing unit 163 identifies a melody registered as the first set level or a function for a specific audio effect set to the first set level. After that, the auxiliary data processing unit 163 adds the melody to audio data 151 to be output or provides the melody as an audio effect, which refers to altered audio data. The auxiliary data processing unit 163 synchronizes a specific melody with audio data 151 and outputs the melody, one or more times, together with the audio data 151.

The data output supporting unit 165 outputs the altered audio data, transferred from the auxiliary data processing unit 163, to the audio processing unit 130. The data output supporting unit 165 receives altitude information from the altitude information collecting unit 161 and automatically controls the volume for the altered audio data according to the received altitude information. For example, if the set level corresponding to the altitude information increases gradually, the data output supporting unit 165 automatically increases or decreases the volume corresponding thereto. On the other hand, if the set level corresponding to the altitude information decreases gradually, the data output supporting unit 165 automatically decreases or increases the volume corresponding thereto. That is, the data output supporting unit 165 can control the level of volume according to the change in the set level. The automatic volume control function may also be applied to a voice or video call function. That is, when a voice or video call function, as a user function corresponding to an audio data output function, is executed, the data output supporting unit 165 can automatically control the volume of audio data according to the altitude information transferred from the altitude information collecting unit 161. For example, if the mobile device is at a location where the altitude information corresponds to a first set level, the data output supporting unit 165 supports an audio data output function at the first volume level. Likewise, if the mobile device 100 is at a location where the altitude information corresponds to a second set level, the data output supporting unit 165 supports an audio data output function at the second volume level. For example, the audio data output function at the second volume level may be a speakerphone call function. That is, although the mobile device user speaks in a relatively soft voice, the data output supporting unit 165 can collect the level of voice as a normal level and transfer it to the other mobile device user. The data output supporting unit 165 receives a voice signal from the other mobile device, amplifies the level of voice, and outputs it at a certain level of voice.

As described above, the mobile device 100 can adaptively alter the property of a user function according to the altitude information. The mobile device 100 can define the output property of audio data and/or the collecting property of audio data, according to the altitude information, and execute the user function according to the defined properties. Therefore, if the mobile device user alters the altitude information regarding the mobile device 100 or the altitude information is automatically altered according to the movement of the mobile device 100, the mobile device 100 executes user functions based on the audio data processing function, according to the altitude alteration.

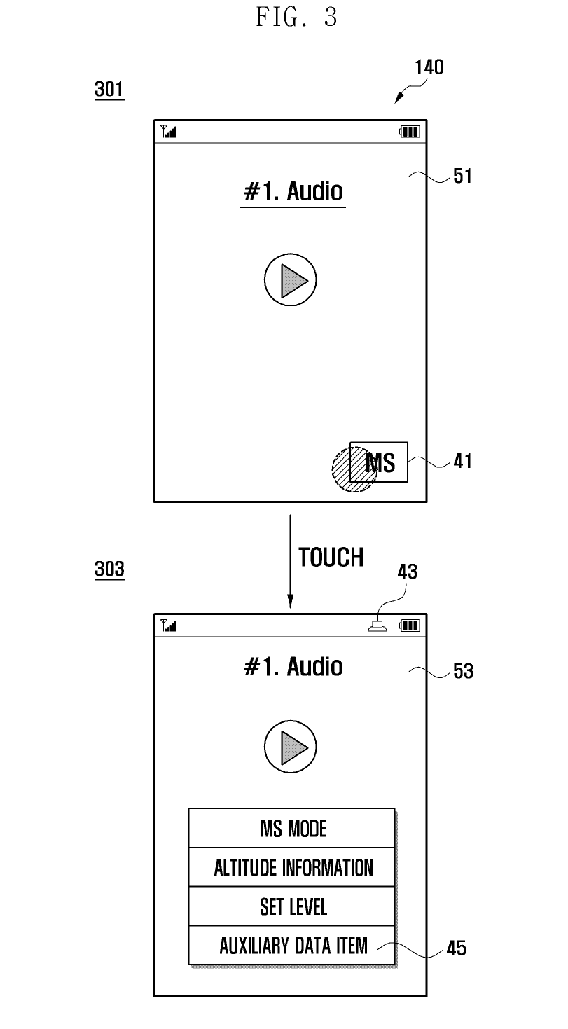

FIG. 3 illustrates screens to describe a method for controlling altitude information-based user functions in a mobile device according to a first exemplary embodiment of the present invention.

Referring to FIG. 3, the mobile device 100 can execute a specific user function according to the user's request. When the user selects a function for outputting audio data that is stored in the storage unit 150 or received from an external system, the mobile device 100 displays a default audio data operating screen 51 to output the audio data as shown in diagram 301. The default audio data operating screen 51 displays an index for the selected audio data, information regarding the output state of the audio data, etc. More particularly, the default audio data operating screen 51 displays a menu or a function button 41 on the screen for setting an audio data altering function. The user operates the function button 41 to execute a user function in an MS mode in which an audio data altering function is executed. The mobile device 100 determines whether the audio data altering function can be applied to a corresponding user function in order to output the function button 41. If the mobile device 100 ascertains that the audio data altering function can be applied to a corresponding user function, it displays the function button 41.

When an input signal for activating the function button 41 is received, i.e., a touch event occurs on the function button 41, the mobile device 100 controls the display unit 140 to display an altered audio data operating screen 53, showing that the audio data altering function, i.e., an MS function, is being applied, as shown in diagram 303. The mobile device 100 activates the sensing unit 170 to support the audio data altering function. The mobile device 100 displays a sensing unit indicating icon 43 for indicating the activation of the sensing unit 170 on the indicator area. Therefore, the user can recognize whether the sensing unit 170 is currently activated according to the state of the sensing unit indicating icon 43.

The mobile device 100 can display a menu or function button for disabling the setting of the MS mode on the altered audio data operating screen 53. When the user selects a corresponding function button, the mobile device 100 displays the default audio data operating screen 51 as shown in diagram 301. In that case, the mobile device 100 disables the sensing unit 170, and also removes the sensing unit indicating icon 43 from the indicator area.

In the foregoing exemplary embodiment, it is assumed that user functions are not set in the MS mode. On the contrary, if a specific user function is set in the MS mode and if an input signal is created to activate the user function, the mobile device 100 controls the display unit 140 to display the altered audio data operating screen 53 as shown in diagram 303. The mobile device 100 controls the display unit 140 to display altitude information collected by the sensing unit 170, a set level corresponding to the altitude information, or auxiliary data item 45 corresponding to the set level, on the screen as shown in diagram 303. The set level refers to a value that is defined according to altitude information, and may be set according to a preset altitude value.

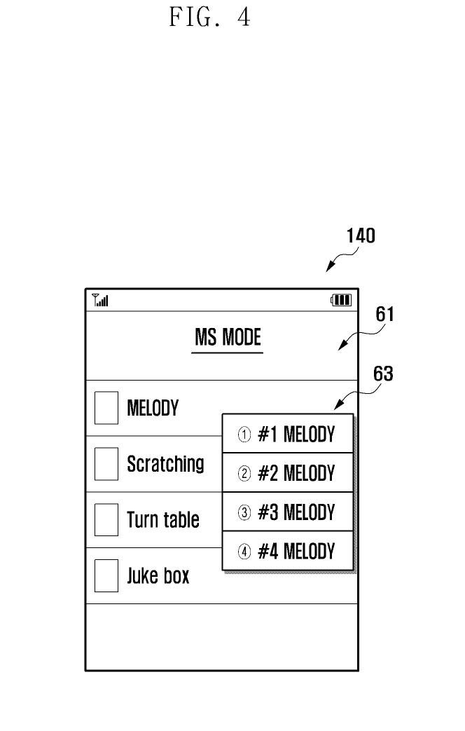

When the auxiliary data item 45 is selected, the mobile device 100 can display a screen for selecting auxiliary data items related to the other functions as shown in FIG. 4.

FIG. 4 illustrates a screen to describe a method for controlling altitude information-based user functions in a mobile device, where the auxiliary data item is selected, according to a second exemplary embodiment of the present invention.

Referring to FIG. 4, the mobile device 100 controls the display unit 140 to display an auxiliary data list screen 61 on which the user selects one of auxiliary data items to which altitude information is applied during the operation of a specific user function. Alternatively, the mobile device 100 controls the display unit 140 to display an auxiliary data list screen 61 when the user selects an input signal to select an auxiliary data item that will be applied to altitude information during the operation of a specific user function. To this end, the mobile device 100 provides a menu or a hot key for outputting the auxiliary data list screen 61. When the user operates the menu or hot key, the mobile device 100 outputs the auxiliary data list screen 61.

The auxiliary data list screen 61 shows a melody item, a scratching function item, a turn-table function item, a jukebox function item, etc. When the melody item is selected, the mobile device 100 controls the display unit 140 to display a melody selection screen 63 on which the user selects one of the melodies. When the user selects a melody on the melody selection screen 63, the mobile device 100 plays back the melody and outputs the corresponding audio sound via the audio processing unit 130. Therefore, the user can recognize a melody that will be applied to the audio data altering function.

Likewise, if one of the scratching function item, the turn-table function item, the jukebox function item, etc. is selected on the auxiliary data list screen 61, the levels of settings provided by the selected item may be mapped to altitude values. After that, the mobile device 100 can apply the settings for the specific user function to audio data 151 according to the current altitude information. Audio data 151 may be altered by synthesizing auxiliary data 153, with set values corresponding to the selected item, with audio data 151, by modulating audio data 151 using auxiliary data 153, or by outputting audio data 151 and auxiliary data 153 at a particular time point synchronized with the audio data 151. Selecting one of the synchronization, modulation, and simultaneous output may be set according to the feature of the selected auxiliary data, the user's selection, or the manufacturers' designs.

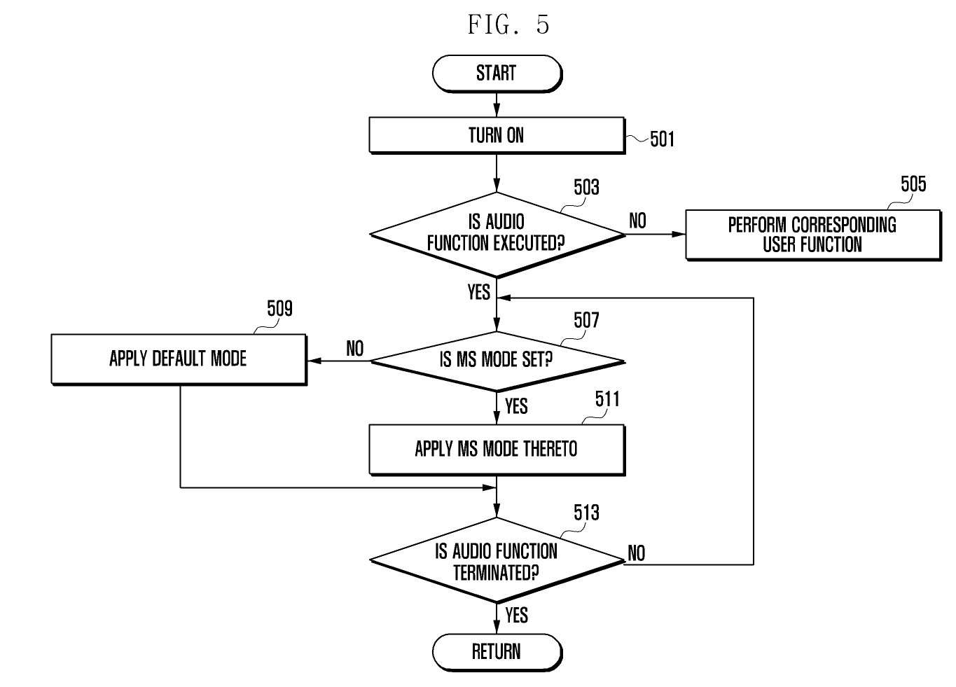

FIG. 5 illustrates a flowchart that describes a method for controlling altitude information-based user functions in a mobile device according to an exemplary embodiment of the present invention.

Referring to FIG. 5, the controller 160 supplies electric power to the components in the mobile device 100 to control them (i.e., turn them on), based on altitude information at step 501. When the controller 160 detects an input signal, it determines whether it corresponds to a signal for executing a user function to which an audio function is applied at step 503. When the controller 160 ascertains that the input signal is not a signal for executing an audio function at step 503, it performs a corresponding user function at step 505. For example, the controller 160 executes a file search function, a web access function, a photograph search function, etc., according to the input signal, at step 505.

On the contrary, when the controller 160 ascertains that the input signal is a signal for executing a user function to which an audio function is applied at step 503, it activates the user function. That is, the controller 160 determines whether an MS mode is set to the user function at step 507. When the controller 160 ascertains that an MS mode is not set to the user function at step 507, it executes the user function in a default mode at step 509. For example, the controller 160 plays back audio data 151 stored in the storage unit 150 and outputs the audio sound, in a default mode, without altering the audio data according to altitude information, in a state where an MP3 function is activated.

On the contrary, when the controller 160 ascertains that an MS mode is set to the user function at step 507, it applies the MS mode to audio data 151 and outputs the audio data 151 at step 511. For example, if an input signal is created to activate an MP3 function for playing back a file corresponding to audio data 151 stored in the storage unit 150 and outputting the audio sound and the MS mode is set to the audio data, the controller 160 activates the sensing unit 170. To this end, the controller 160 supplies electric power to the sensing unit 170 and initializes it. The controller 160 receives altitude information collected by the sensing unit 170. The controller 160 compares the received altitude information with a preset level to detect the level. After that, the controller 160 identifies auxiliary data 153 corresponding to the level of the received altitude information. The controller 160 applies the identified auxiliary data 153 to the audio data 151 that will be currently output, thereby creating the altered audio data. During this process, the controller 160 can create altered audio data according to the types or features of auxiliary data 153, by synthesizing the audio data 151 with the auxiliary data 153, modulating the audio data 151 based on the auxiliary data 153, or synchronizing the audio data 151 with the auxiliary data 153. The controller 160 outputs the altered audio data via the audio processing unit 130.

During this process, the controller 160 can sense the change in altitude information, in real time, or at a certain time point. If the controller 160 ascertains that altitude information is altered, it re-selects auxiliary data corresponding to the altered altitude information, creates altered audio data based on the re-selected auxiliary data, and outputs it.

After applying the MS mode to the audio data at step 511, the controller 160 determines whether an input signal is created to terminate the audio function at step 513. When the controller 160 ascertains that an input signal is not created to terminate the audio function at step 513, it returns to and proceeds with step 507. On the contrary, when the controller 160 ascertains that an input signal is created to terminate the audio function at step 513, it returns to and proceeds with a step before step 501 or 503.

As described above, exemplary embodiments of the invention provide a method for controlling an altitude information-based user function in a mobile device that applies auxiliary data 153 to audio data 151 that will be output, according to the change in altitude information, and thus outputs the altered audio data in various formats. Therefore, the mobile device adapted to the method also outputs the altered audio data in various formats according to the change in altitude information, so that the user can enjoy a variety of user functions.

As described above, the inventive method for controlling altitude information-based user functions and the mobile device adapted thereto can create auxiliary data for supporting user functions, according to altitude information regarding a location of the mobile device, synthesize the created data with audio data to be output, modulate them, and output them.

Although it is not shown in the drawings, the mobile device may selectively further include various types of components such as a short-range communication module for short-range communication, a camera module for acquiring still images/videos, an interface for transmitting/receiving data in a wireless or weird mode; an Internet communication module, and a digital broadcast module for receiving and reproducing broadcasts. With the spread of digital convergence, although it is impossible to list all the modifications of mobile devices in this description, it will be easily appreciated to those skilled in the art that other components equivalent to the above-listed components may be further included in the mobile device according to the invention. Also, it will be appreciated that, according to the purposes, the mobile device may be implemented by omitting a particular component or replacing it with other components.

The mobile device according to exemplary embodiments of the invention includes all information communication devices, multimedia devices, and their applications, which include an earphone interface that various types of jacks for earphones are plugged into and are operated according to communication protocols corresponding to various types of communication systems. For example, the mobile device can be applied to mobile communication terminals, Portable Multimedia Players (PMPs), digital broadcast players, Personal Digital Assistants (PDAs), audio players (e.g., MP3 players), mobile game players, smartphones, laptop computers, hand-held PC, etc.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A method for controlling altitude information-based user functions, the method comprising:
receiving a request for activation of a user function;
activating a sensing unit according to the activated user function;
collecting, by the sensing unit, altitude information;
creating altered audio data by applying predefined auxiliary data to audio data that will be output when the user function is executed, according to the altitude information; and
outputting the altered audio data.

2. The method of claim 1, further comprising:
determining whether the activated user function supports an audio function; and
identifying, if the activated user function supports the audio function, whether an audio data altering function is set to the user function.

3. The method of claim 2, further comprising:
outputting, if the audio data altering function is set to the user function, a function button for setting the audio data altering function on a user function operating screen.

4. The method of claim 3, further comprising:
outputting, if an input is received on the function button, an altered audio data operating screen indicating application of the audio data altering function.

5. The method of claim 2, further comprising:
outputting an icon for indicating the activation of the sensing unit on a user function operating screen.

6. The method of claim 5, further comprising:
removing, if the setting of the audio data altering function is released, the icon from the user function operating screen.

7. The method of claim 1, further comprising:
outputting, on a user function operating screen, at least one of the altitude information, a set level corresponding to the altitude information, and an auxiliary data item that will be applied to the audio data according to the set level.

8. The method of claim 7, further comprising:
automatically controlling the sound volume of the altered audio data according to the set level.

9. The method of claim 7, further comprising:
displaying, when the auxiliary data item is selected, a list of other auxiliary data items on an auxiliary data list screen.

10. The method of claim 1, wherein the creating of the altered audio data comprises at least one of modulating the audio data based on the auxiliary data, synthesizing the audio data with the auxiliary data, and synchronizing the auxiliary data with the audio data to simultaneously output them.

11. A mobile device that supports altitude information-based user functions, the mobile device comprising:
a storage unit for storing audio data that will be output according to activation of a user function, and auxiliary data that will be applied to the audio data if an audio data altering function is set when the user function is activated;
a sensing unit for collecting altitude information to set auxiliary data that will be applied to the audio data according to the activation of the user function;
a controller for creating altered audio data by applying predefined auxiliary data to audio data that will be output when the user function is executed, according to the altitude information; and
an audio processing unit for outputting the altered audio data.

12. The mobile device of claim 11, wherein the controller determines whether the activated user function supports an audio function, and outputs, if the activated user function supports the audio function, a function button for setting the audio data altering function.

13. The mobile device of claim 12, further comprising:
a display unit for displaying the function button on a user function operating screen.

14. The mobile device of claim 13, wherein the display unit displays, if an input is received on the function button, an altered audio data operating screen indicating application of the audio data altering function.

15. The mobile device of claim 12, further comprising:
a display unit for displaying an icon for indicating an activation of the sensing unit on a user function operating screen.

16. The mobile device of claim 15, wherein the display unit removes, if the setting of the audio data altering function is released, the icon from the user function operating screen.

17. The mobile device of claim 11, further comprising:
a display unit for outputting, on a user function operating screen, at least one of the altitude information, a set level corresponding to the altitude information, and an auxiliary data item that will be applied to the audio data according to the set level.

18. The mobile device of claim 17, wherein the controller automatically controls the sound volume of the altered audio data according to the set level.

19. The mobile device of claim 17, wherein the display unit displays, when the auxiliary data item is selected, a list of other auxiliary data items on an auxiliary data list screen.

20. The mobile device of claim 11, wherein the controller modulates the audio data based on the auxiliary data, synthesizes the audio data with the auxiliary data, or synchronizes the auxiliary data with the audio data to simultaneously output them.
